(19) United States
(12) Patent Application Publication
(10) Pub. No.: US 2024/0103577 A1
(43) Pub. Date: Mar. 28, 2024

(54) BACK COVER COUPLING FOR ELECTRONIC DEVICES

(71) Applicant: Hewlett-Packard Development Company, L.P., Spring, TX (US)

(72) Inventors: Cheng-Yi Yang, Taipei City (TW); Szu Tao Tong, Taipei City (TW); Hai-Lung Hung, Taipei City (TW)

(73) Assignee: Hewlett-Packard Development Company, L.P., Spring, TX (US)

(21) Appl. No.: 17/768,492

(22) PCT Filed: Nov. 5, 2019
(86) PCT No.: PCT/US2019/059736

§ 371 Date: Apr. 13, 2022

(51) Int. Cl. G06F 1/16

(52) U.S. Cl. CPC G06F 1/1656; G06F 1/1626

(57) ABSTRACT

In one example, an electronic device may include a main body, and a back cover having an opening. The back cover may include an inner surface, and a hook protruding from the inner surface. The hook may be engageable with a receiving portion of the main body to slidably couple the back cover to the main body. Further, electronic device may include a component housing connected to the main body through the opening in the back cover to fixedly couple the back cover to the main body.

### BACKGROUND

Personal computers may provide a variety of physical shapes and configurations ranging from a notebook computer, which compactly packages a keyboard, several operating electronics, and a monitor into a single portable package, to a desktop computer which may include separate computer, monitor, keyboard, and speaker components gathered together with other separate computing accessories. Occupying a middle ground between these two computer systems is a personal computer platform commonly referred to as an all-in-one computer. In all-in-one computers, although a separate keyboard may be required, the monitor and other electronic components, such as a motherboard, a hard disk, a speaker, a power supply, or the like are assembled in a single housing structure. A point of sale (POS) computer may be an example of the all-in-one computer in the service industry.

### BRIEF DESCRIPTION OF THE DRAWINGS

Examples are described in the following detailed description and in reference to the drawings, in which:

FIG. 1A illustrates a side view of an example electronic device, depicting a hook and a component housing to couple a back cover to a main body;

FIG. 1B is a perspective view of the example electronic device of FIG. 1A, depicting additional features;

FIG. 1C is an enlarged view of a portion of the example electronic device of FIG. 1A, depicting additional features;

FIG. 2A illustrates a perspective view of an all-in-one personal computer, depicting a component housing to couple a back cover to a main body;

FIG. 2B is a perspective view of the example all-in-one personal computer of FIG. 2A, depicting additional features;

FIG. 2C illustrates an enlarged view of a portion of the all-in-one personal computer of FIG. 2A, depicting a component cover and a latch to lock the component cover;

FIG. 3A illustrates a perspective view of a point of sale device, depicting a component housing and hooks to fixedly couple a back cover to a main body:

FIG. 3B illustrates an enlarged view of a portion of the point of sale device, depicting a component cover and cables routed through the component cover; and

FIGS. 4A-4H illustrate example sequence diagrams illustrating a mechanism for coupling a back cover to a main body of an electronic device.

### DETAILED DESCRIPTION

Electronic devices, such as all-in-one personal computers, may include a main body and a back cover cooperating with the main body to form a receiving space for receiving electronic components. The back cover may be connected to the electronic device using fasteners such as screws. However, using fasteners to secure the back cover having an exterior cosmetic surface may result in a visible opening or at least a fastener head being visible after the electronic device is assembled. The exposed fasteners may affect the aesthetic appearance of the electronic devices. Furthermore, in some examples, the visibility of an external fastener may also allow to access components disposed within the electronic devices. In electronic devices involving tamper resistance, a readily visible fastener can be undesirable. Also, the assembly and disassembly process using the fasteners may be cumbersome as the fasteners can be slipped.

Examples described herein may provide an electronic device including a main body and a back cover. The back cover may include a hook protruding from an inner surface. The hook may be engageable with a receiving portion of the main body to slidably couple the back cover to the main body. The hook may constrain a movement of the back cover relative to the main body in a Z direction. Further, the electronic device may include a component housing connected to the main body through an opening in the back cover to fixedly couple the back cover to the main body.

The component housing may constrain the movement of the back cover relative to the main body in X and Y directions. In one example, the component housing may accommodate cable connectors (e.g., Ethernet connector, USB type-C connector, and the like) when the cable connectors are connected to ports of the electronic device. Thus, examples described herein may improve the aesthetic appearance of the electronic devices as no screws and/or cable connectors can be exposed after installation and also provide an enhanced mechanical strength.

In the following description, for purposes of explanation, numerous specific details are set forth in order to provide a thorough understanding of the present techniques. It will be apparent, however, to one skilled in the art that the present apparatus, devices and systems may be practiced without these specific details. Reference in the specification to “an example” or similar language means that a particular feature, structure, or characteristic described is included in at least that one example, but not necessarily in other examples.

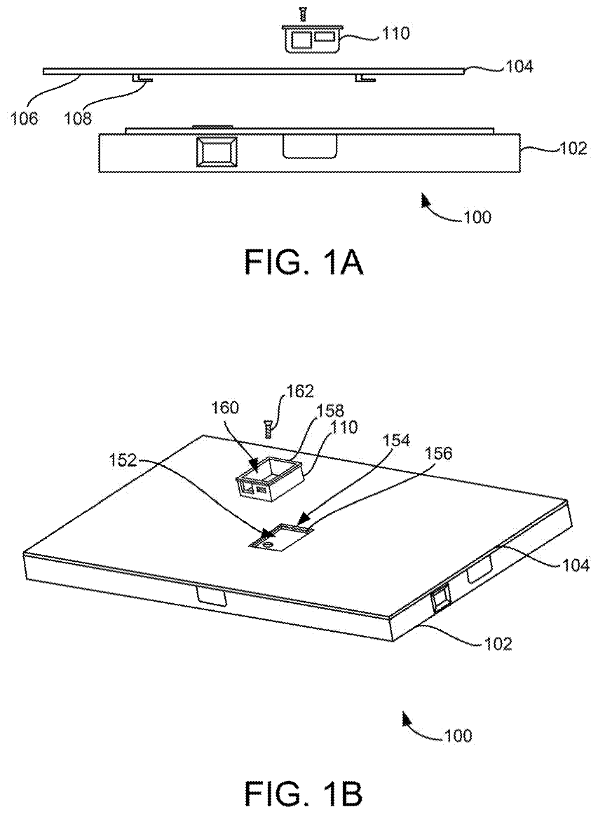

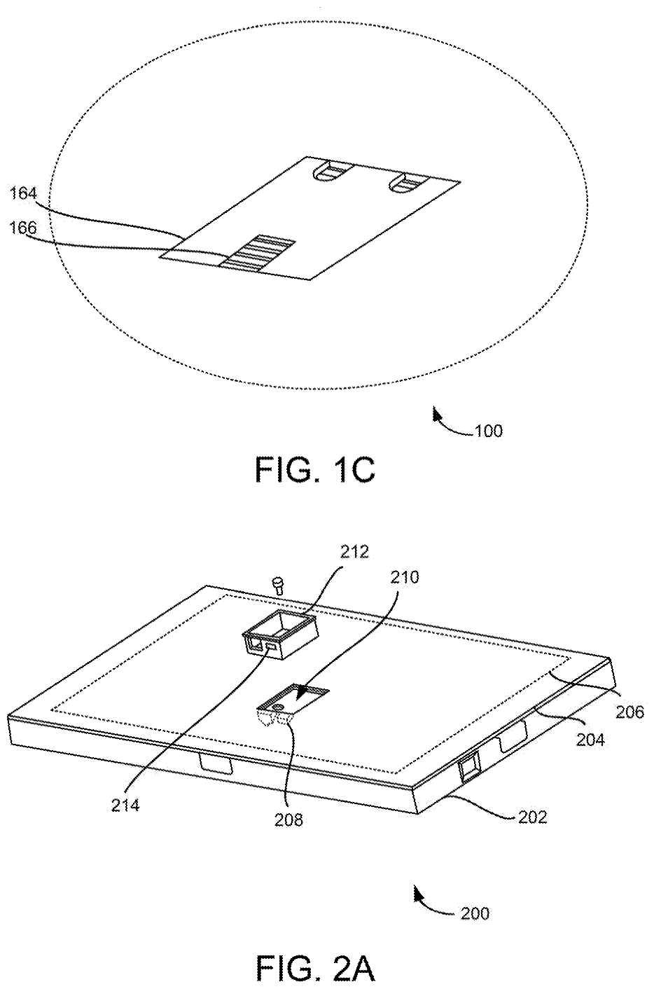

Turning now to the figures, FIG. 1A illustrates a side view of an example electronic device 100, depicting a hook 108 and a component housing 110 to couple a back cover 104 to a main body 102. Example electronic device 100 may include an all-in-one computer. The all-in-one computer may be a personal computer (PC), in which the monitor and other electronic components, such as a motherboard, a hard disk, a power supply, or the like may be assembled in a single housing structure. A point of sale (POS) computer may be an example of the all-in-one computer in the service industry. In other examples, electronic device 100 may also include a television, a monitor, a laptop computer, or the like.

Example electronic device may include main body 102 and back cover 104 having an opening (e.g., opening 152 as shown in FIG. 18). Back cover 104 may include an inner surface 106 and hook 108 protruding from inner surface 106. In one example, hook 108 may be engageable with a receiving portion of main body 102 to slidably couple back cover 104 to main body 102.

Further, electronic device 100 may include component housing 110 connected to main body 102 through the opening in back cover 104 to fixedly couple back cover 104 to main body 102. For example, component housing 110 may house an electronic component such as a battery, a mating connector, a USB device, and the like.

FIG. 1B is a perspective view of example electronic device 100 of FIG. 1A, depicting additional features. For example, similarly named elements of FIG. 1B may be similar in structure and/or function to elements described with respect to FIG. 1A. As shown in FIG. 1B, back cover 104 may include a step-shaped recess 154 at a boundary defining opening 152. In one example, step-shaped recess 154 may include a step 156 that contacts an end portion 158 defining an opening 160 of component housing 110. Component housing 110 may include a space to accommodate an electronic component, such as a battery, an external USB device, a mating connector of a cable, and the like, when the electronic component is connected to electronic device 100. Example component housing 110 may include a base (e.g., at a bottom side) and side walls disposed on the base such that opening 160 can be formed at a top side. In one example, component housing 110 may be connected to main body 102 through a fastener 162. Example fastener 162 may be a screw.

FIG. 1C is an enlarged view of a portion of example electronic device 100 of FIG. 1A, depicting additional features. For example, similarly named elements of FIG. 1C may be similar in structure and/or function to elements described with respect to FIG. 1A. As shown in FIG. 10, electronic device 100 may include a component cover 164 disposed on component housing 110 (e.g., as shown in FIG. 1B) to cover opening 160 (e.g., as shown in FIG. 1B) of component housing 110. Furthermore, electronic device 100 may include a latch 166 to lock component cover 164. In one example, latch 166 may be provided on component cover 164. Further as shown in FIG. 1C, an outer surface of component cover 164 may be positioned at a substantially same height as an outer surface of back cover 104, when component cover 164 is locked to component housing 110.

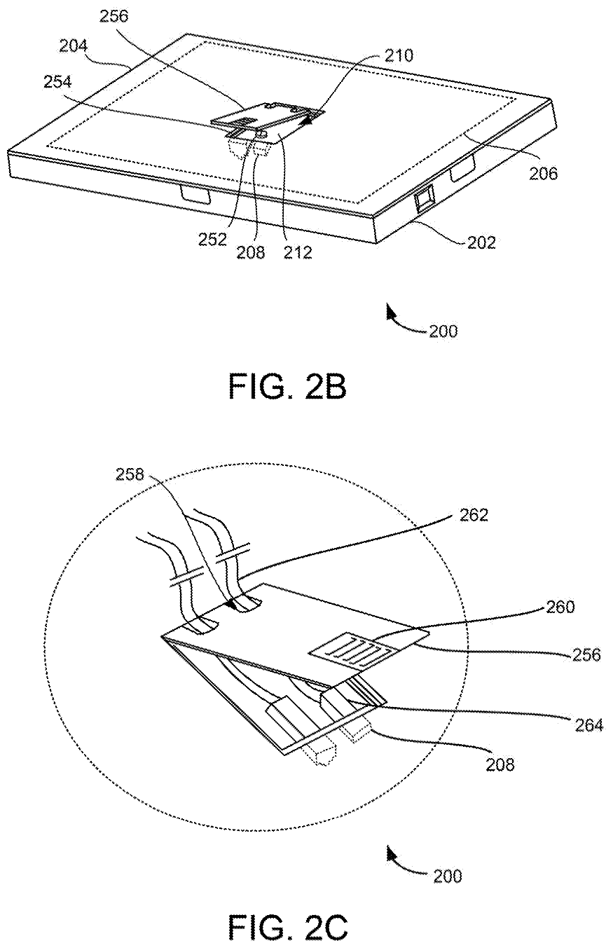

FIG. 2A illustrates a perspective view of an all-in-one personal computer 200, depicting a component housing 212 to couple a back cover 204 to a main body 202. Particularly, FIG. 2A depicts a rear-side view of all-in-one personal computer 200. All-in-one personal computer 200 may include main body 202. Main body 202 may include a circuit board 206 and a port 208 disposed on circuit board 206 for connecting with a peripheral device. Example circuit board 206 may be a motherboard that includes a variety of interface ports for connecting a variety of peripherals and providing network connectivity. Example interface ports may include a Universal Serial Bus (USB) connector. Ethernet connector, audio connector, video connector, power connector, or the like.

Further, all-in-one personal computer 200 may include back cover 204 having an opening 210. For example, back cover 204 may include an inner surface and a hook protruding from the inner surface. The hook may be engageable with a receiving portion of main body 202 to slidably couple back cover 204 to main body 202. In one example, port 208 may be exposed in opening 210 to engage with a cable connector. An example hook is shown in FIG. 1A.

Further, all-in-one personal computer 200 may include component housing 212 that can be connected to main body 202 through opening 210 in back cover 204 to fixedly couple back cover 204 to main body 202. In one example, component housing 210 may include an opening 214 corresponding to port 208 to enable the cable connector to connect to port 208,

FIG. 2B is a perspective view of example all-in-one personal computer 200 of FIG. 2A, depicting additional features. For example, similarly named elements of FIG. 2B may be similar in structure and/or function to elements described with respect to FIG. 2A. As shown in FIG. 2B, component housing 212 may be connected to main body 202 through fastener 252. In this example, main body 202 may include a recess portion corresponding to opening 210 to receive component housing 212. Back cover 204 may include a step-shaped recess 254 at a boundary defining opening 210. In one example, step-shaped recess 254 may include a step that contacts an end portion defining an opening of component housing 212. Further, all-in-one personal computer may include a component cover 256 disposed on component housing 212 to shield an opening of component housing 212.

FIG. 2C illustrates an enlarged view of a portion of all-in-one personal computer 200, depicting component cover 256 and a latch 260 to lock component cover 256. For example, similarly named elements of FIG. 2C may be similar in structure and/or function to elements described with respect to FIGS. 2A and 2B. As shown in FIG. 2C, all-in-one personal computer may include a latch 260 to lock component cover 256. Further, as shown in FIG. 2C, a cable connector 264 is connected to port 208 through opening 214 (e.g., as shown in FIG. 2A). Further, component cover 256 may include an opening 258 to route a cable 262 associated with cable connector 264 between port 208 and the external peripheral device. In some examples, all-in-one personal computer 200 may include a stand disposed on a surface of back cover 204 and is rotatable relative to the surface,

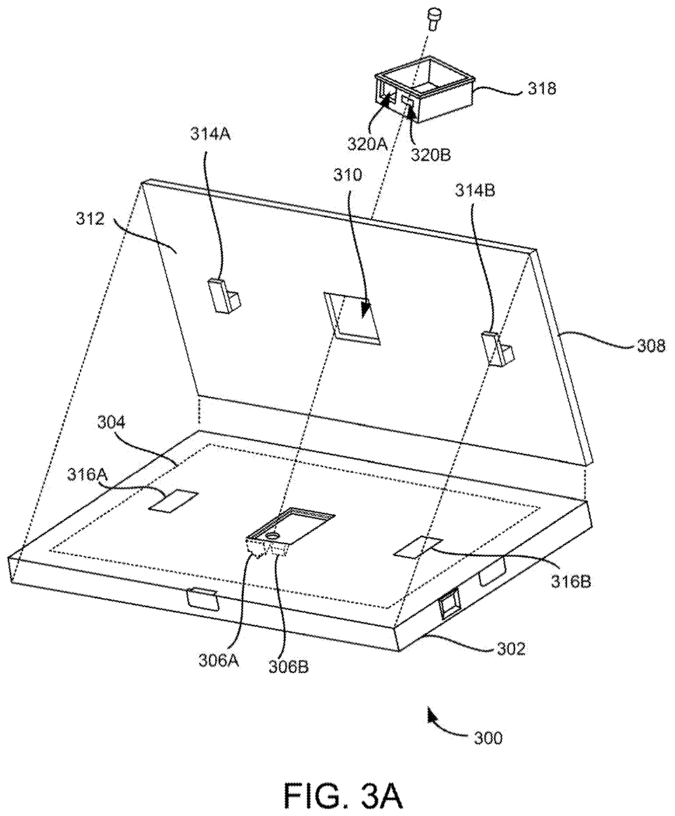

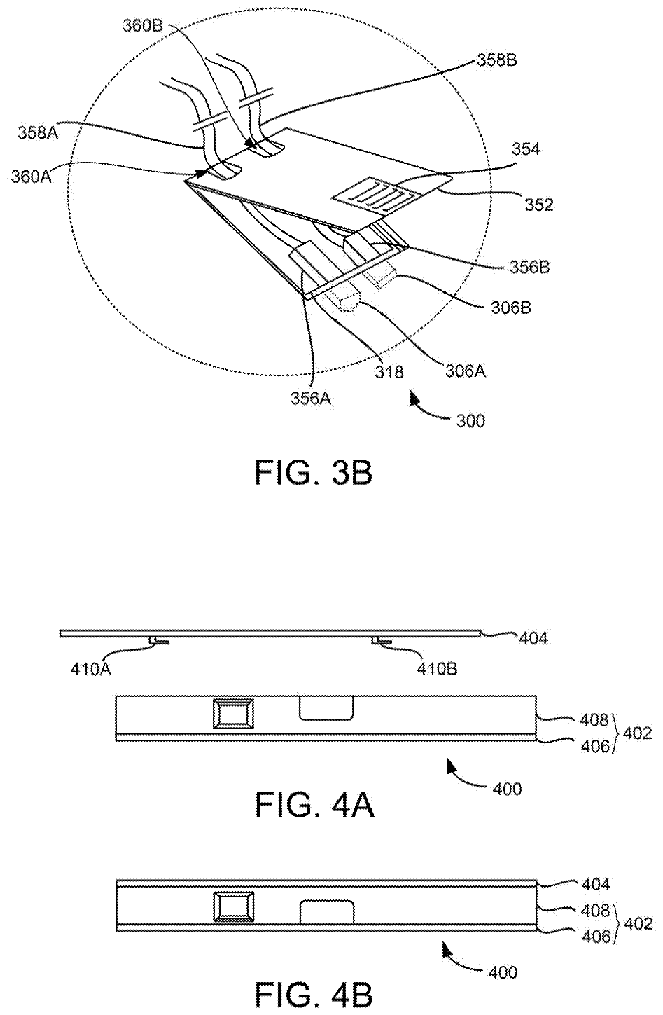

FIG. 3A illustrates a perspective view of a point of sale device 300, depicting a component housing 318 and hooks 314A and 314B to fixedly couple a back cover 308 to a main body 302. Point of sale device 300 may include main body 302. Main body 302 may include a circuit board 304 and first and second ports 306A and 306B connected to circuit board 304 for connecting with peripheral devices. In one example, first port 306A and second port 306B may include an Ethernet connector and a USB connector, respectively. In other examples, ports 306A and 306B may be include USB ports, serial ports, parallel ports. Ethernet ports, or any combination thereof.

Example circuit board 304 may be a motherboard that includes a variety of interface ports for connecting a variety of peripheral devices and providing network connectivity. For example, the motherboard may include a variety of communication ports for interfacing peripheral devices through USB connections, Ethernet connections, General Purpose Input/Output (GPIO) connections, display connections, a cash drawer connection, and others. Example peripheral devices may include printers, cash drawers, additional scanners, additional cameras, keyboards, security tag removers, and the like that may be connected to point of sale device 300 via respective ports to facilitate various point of sale tasks. In other examples, a monitor, a hard disk, a power supply, a heat sink module, and a first peripheral interface module, and the like may be disposed in main body 302 and electrically connected to motherboard 304.

Point of sale device 300 may include back cover 308 having a first opening 310 and may be assembled onto a back end of point of sale device 300. Back cover 308 may include an inner surface 312 and a hook (e.g., hooks 314A and 314B) protruding from inner surface 312. As shown in FIG. 3, hooks 314A and 314B may be engageable with respective receiving portions 316A and 316B of main body 302 to constrain a movement of back cover 308 relative to main body 302 in a first direction (i.e., Z direction). To facilitate the sliding, main body 302 may include receiving portions 316A and 316B such as grooves or other suitable guides to lead back cover 308 into main body 302. When back cover 308 is connected to main body 302, hooks 314A and 314B may be passed through respective receiving portions 316A and 316B to constrain the movement of back cover 308 relative to main body 302 in the Z direction.

Further, point of sale device 300 may include component housing 318 that can be connected to main body 302 through first opening 310 to constrain the movement of back cover 308 relative to main body 302 in second and third directions (i.e., X and Y directions). Furthermore, component housing 318 may include second and third openings 320A and 320B corresponding to first and second ports 306A and 306B to enable first and second cable connectors (e.g., connectors 356A and 356B as shown in FIG. 3B) to engage with first and second ports 306A and 3061, respectively.

FIG. 3B illustrates an enlarged view of a portion of point of sale device 300, depicting a component cover 352 and cables 358A and 358B routed through component cover 352. As shown in FIG. 3B, component housing 318 may accommodate the first and second cable connectors 356A and 356B of first and second cables 358A and 358B, respectively, when first and second cable connectors 356A and 356B are connected to first and second ports 306A and 3068, respectively.

As shown in FIG. 38, point of sale device 300 may include component cover 352 disposed on a top side of component housing 318 to shield first and second cable connectors 356A and 356B disposed in component housing 318. In one example, component cover 352 may include a fourth opening 360A to route first cable 358A associated with first cable connector 356A between first port 306A and a first external peripheral device. In another example, component cover 352 may include a fifth opening 360B to route second cable 358B associated with second cable connector 358B between second port 306B and a second external peripheral device. In addition, point of sale device 300 may include a latch 354 to lock component cover 352.

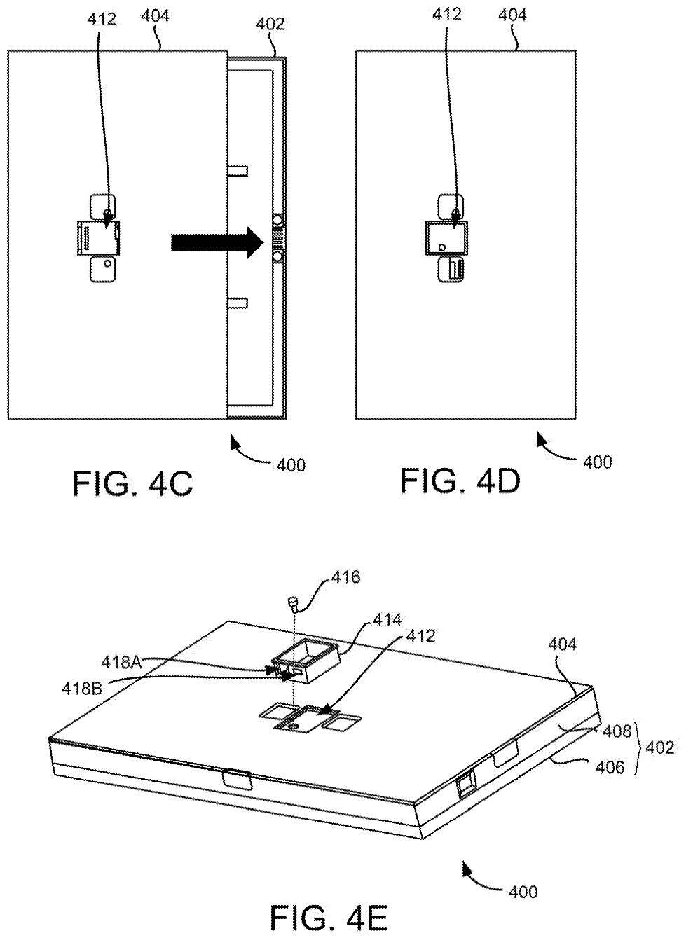

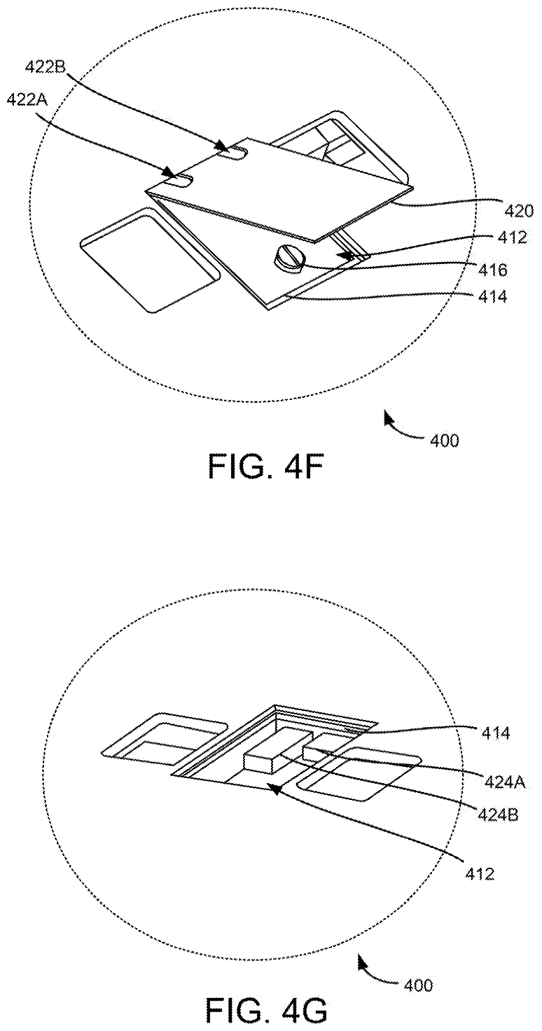

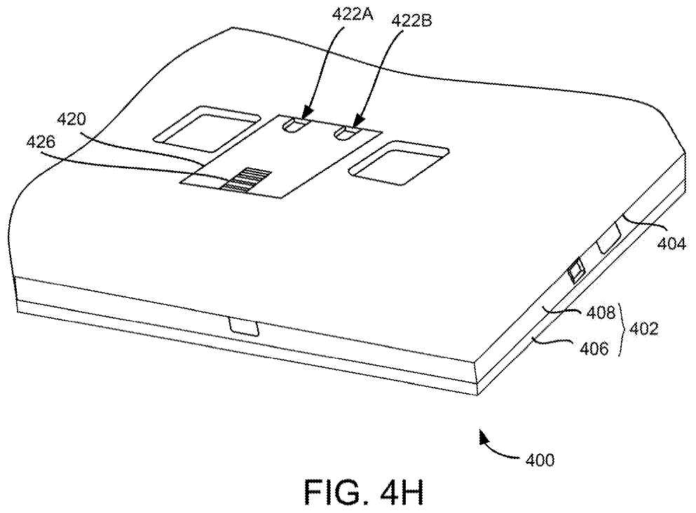

FIGS. 4A-4H illustrate example sequence diagrams illustrating a mechanism for coupling a back cover 404 to a main body 402 of an electronic device 400. Particularly, FIG. 4A illustrates a side view of electronic device 400 before slidably coupling back cover 404 to main body 402. As shown in FIG. 4A, electronic device 400 may include main body 402. Main body 402 may include a display panel 406 at a front end of electronic device 400 and a frame 408 to support display panel 406. Further, electronic device 400 may include back cover 404 disposed at a rear end of electronic device 400.

As shown in FIG. 4A, back cover 404 may include a pair of hooks 410A and 410B. Example hooks 410A and 410B may be L-shaped features protruding from an inner surface of back cover 404. FIG. 4B illustrates a side view of electronic device 400 after slidably coupling back cover 404 and main body 402. Hooks 410A and 4108 may constrain a movement of back cover 404 relative to main body 402 in the Z direction. FIG. 40 corresponds to FIG. 4A and illustrates a top view of electronic device 400 before slidably coupling back cover 404 and main body 402. FIG. 4D corresponds to FIG. 4B and illustrates a top view of electronic device 400 after slidably coupling back cover 404 and main body 402. As shown in FIGS. 4C and 4D, back cover 404 may include an opening 412.

FIG. 4C shows a positioning of main body 402 and back cover 404 and thereafter back cover 404 has been slid into place in a direction shown by arrow in FIG. 4C. As illustrated in FIG. 4D, after back cover 404 has been slid into place, hooks 410A and 410B can lock to respective receiving portions of main body 402 to constrain the movement of back cover 404 relative to main body 402 in the Z direction.

FIG. 4E illustrates a perspective view of electronic device 400, depicting a component housing 414 to fixedly couple back cover 404 and main body 402. As shown in FIG. 4E, component housing 414 may be connected to main body 402 through a screw 416 via opening 412. In one example, component housing 414 may constrain the movement of back cover 404 relative to main body 402 in X and Y directions. Also, component housing 414 may include openings 418A and 418B corresponding to ports (e.g., USB Type-C and RJ45 ports) in main body 402 to enable cable connectors to connect to the ports. For example, USB Type-C connector may transmit both data and power on a single cable while RJ45 port is used to connect electronic device 400 onto an Ethernet-based local area network (LAN),

FIG. 4F is an enlarged view of a portion of example electronic device 400 of FIG. 4E, depicting a component cover 420 disposed on component housing 414 to cover an opening of component housing 414. Further, component cover 420 may include openings/slots 422A and 422B.

FIG. 43 is an enlarged view of a portion of example electronic device 400 of FIG. 4E, depicting cable connectors 424A and 424B that are connected to the ports via openings 418A and 418B, FIG. 4H is a perspective view of a portion of example electronic device 400 of FIG. 4F, depicting a latch 426 on component cover 420 to lock component cover 420, for instance, to back cover 404. Further, cables associated with cable connectors 424A and 424B may routed to external peripheral devices via respective openings 422A and 422B. Thus, examples described herein may improve the aesthetic appearance of the electronic devices as no screws and/or cable connectors can be exposed after installation and also provide an enhanced mechanical strength.

It may be noted that the above-described examples of the present solution are for the purpose of illustration only. Although the solution has been described in conjunction with a specific implementation thereof, numerous modifications may be possible without materially departing from the teachings and advantages of the subject matter described herein. Other substitutions, modifications and changes may be made without departing from the spirit of the present solution. All of the features disclosed in this specification (including any accompanying claims, abstract, and drawings), and/or all of the steps of any method or process so disclosed, may be combined in any combination, except combinations where at least some of such features and/or steps are mutually exclusive.

The terms “include,” “have,” and variations thereof, as used herein, have the same meaning as the term “comprise” or appropriate variation thereof. Furthermore, the term “based on”, as used herein, means “based at least in part on,” Thus, a feature that is described as based on some stimulus can be based on the stimulus or a combination of stimuli including the stimulus.

The present description has been shown and described with reference to the foregoing examples. It is understood, however, that other forms, details, and examples can be made without departing from the spirit and scope of the present subject matter that is defined in the following claims.

What is claimed is:

1. An electronic device comprising:
a main body;
a back cover having an opening, the back cover comprising:
an inner surface; and
a hook protruding from the inner surface, wherein the hook is engageable with a receiving portion of the main body to slidably couple the back cover to the main body; and
a component housing connected to the main body through the opening in the back cover to fixedly couple the back cover to the main body.

2. The electronic device of claim 1, wherein the back cover comprises a step-shaped recess at a boundary defining the opening, and wherein the step-shaped recess includes a step that contacts an end portion defining an opening of the component housing.

3. The electronic device of claim 1, further comprising:
a component cover disposed on the component housing to cover an opening of the component housing; and
a latch to lock the component cover.

4. The electronic device of claim 3, wherein an outer surface of the component cover is positioned at a substantially same height as an outer surface of the back cover.

5. The electronic device of claim 1, wherein the component housing is connected to the main body through a fastener.

6. An all-in-one personal computer comprising:
a main body comprising:
a circuit board; and
a port disposed on the circuit board for connecting with a peripheral device;
a back cover having an opening, the back cover comprising:
an inner surface; and
a hook protruding from the inner surface, wherein the hook is engageable with a receiving portion of the main body to slidably couple the back cover to the main body; and
a component housing connected to the main body through the opening in the back cover to fixedly couple the back cover to the main body, wherein the component housing comprises an opening corresponding to the port to enable a cable connector to connect to the port.

7. The all-in-one personal computer of claim 6, wherein the back cover comprises a step-shaped recess at a boundary defining the opening, and wherein the step-shaped recess includes a step that contacts an end portion defining an opening of the component housing.

8. The all-in-one personal computer of claim 6, further comprising:
a component cover disposed on the component housing to shield an opening of the component housing; and
a latch to lock the component cover.

9. The all-in-one personal computer of claim 8, wherein the component cover comprises an opening to route a cable associated with the cable connector between the port and the peripheral device.

10. The all-in-one personal computer of claim 6, wherein the port comprises a Universal Serial Bus (USB) connector, Ethernet connector, audio connector, video connector, or power connector.

11. A point of sale device comprising:
a main body comprising:
a circuit board; and
first and second ports connected to the circuit board;
a back cover having a first opening, the back cover comprising:
an inner surface; and
a hook protruding from the inner surface, wherein the hook is engageable with a receiving portion of the main body to constrain a movement of the back cover relative to the main body in a first direction; and
a component housing connected to the main body through the first opening to constrain the movement of the back cover relative to the main body in second and third directions, wherein the component housing comprises second and third openings corresponding to the first and second ports to enable first and second cable connectors to engage with the first and second ports, respectively.

12. The point of sale device of claim 11, wherein the first port and the second port comprise an Ethernet connector and a USB connector, respectively.

13. The point of sale device of claim 11, wherein the component housing is to accommodate the first and second cable connectors of first and second cables, respectively, when the first and second cable connectors are connected to the first and second ports.

14. The point of sale device of claim 11, further comprising:
a component cover disposed on a top side of the component housing to shield the first and second cable connectors disposed in the component housing, wherein the component cover comprises:
a fourth opening to route a first cable associated with the first cable connector between the first port and a first external peripheral device; and
a fifth opening to route a second cable associated with the second cable connector between the second port and a second external peripheral device.

15. The point of sale device of claim 11, wherein the main body comprises:
a display panel; and
a frame to support the display panel, wherein the back cover is disposed at a rear end of the main body.
